(19) United States
(12) Patent Application Publication
(10) Pub. No.: US 2026/0264366 A1
(43) Pub. Date: Sep. 10, 2026

(54) MULTILAYER SUBSTRATE

(71) Applicant: KYOCERA Corporation, Kyoto-shi, Kyoto (JP)

(72) Inventors: Yuhei MATSUMOTO, Kirishima-shi, Kagoshima (JP); Sentarou YAMAMOTO, Kagoshima-shi, Kagoshima (JP); Yukio MORITA, Kirishima-shi, Kagoshima (JP); Kazuki NISHIMOTO, Kirishima-shi, Kagoshima (JP)

(73) Assignee: KYOCERA Corporation, Kyoto-shi, Kyoto (JP)

(21) Appl. No.: 19/165,662

(22) PCT Filed: Mar. 13, 2024
(86) PCT No.: PCT/JP2024/009894

§ 371 Date: Sep. 16, 2025

(30) Foreign Application Priority Data
Mar. 24, 2023 (JP) 2023-048191

(51) Int. Cl. B32B 9/00; B32B 3/26; B32B 9/04; B32B 27/18

(52) U.S. Cl. CPC B32B 9/007; B32B 3/266; B32B 9/045; B32B 27/18; B32B 2250/02; B32B 2250/03; B32B 2250/04; B32B 2264/108; B32B 2307/302

(57) ABSTRACT

A multilayer substrate includes a carbonaceous base member layer and an organic resin layer. The organic resin layer is located on the carbonaceous base member layer. The carbonaceous base member layer has a higher coefficient of thermal conductivity than that of the organic resin layer.

### CROSS-REFERENCE TO RELATED APPLICATIONS

This application is national stage application of International Application No. JP2024/009894, filed on Mar. 13, 2024 which designates the United States, incorporated herein by reference, and which claims the benefit of priority from Japanese Patent Application No. 2023-048191, filed on Mar. 24, 2023 the entire contents of which are incorporated herein by reference.

### TECHNICAL FIELD

The disclosed embodiments relate to a multilayer substrate.

### BACKGROUND OF INVENTION

A display device having a structure with a multilayer structure in which a wiring is arranged between a plurality of insulation layers has been proposed.

### CITATION LIST

### Patent Literature

Patent Document 1: WO 2021/187090.

### SUMMARY

A multilayer substrate according to an aspect of an embodiment includes a carbonaceous base member layer and an organic resin layer. The organic resin layer is located on the carbonaceous base member layer. The carbonaceous base member layer has a higher coefficient of thermal conductivity than that of the organic resin layer.

### BRIEF DESCRIPTION OF THE DRAWINGS

FIG. 1 is a cross-sectional view illustrating an example of a multilayer substrate according to a first embodiment.

FIG. 2 is a cross-sectional view illustrating an example of a multilayer substrate according to a second embodiment.

FIG. 3A is a cross-sectional view illustrating an example of a multilayer substrate according to a third embodiment.

FIG. 3B is a cross-sectional view taken along line A-A illustrated in FIG. 3A.

FIG. 4 is a cross-sectional view illustrating an example of a multilayer substrate according to a fourth embodiment.

### DESCRIPTION OF EMBODIMENTS

The structure with a multilayer structure described above has room for improvement in terms of enhancing heat dissipation.

Therefore, provision of a multilayer substrate that can improve heat dissipation is expected.

Modes (hereinafter referred to as “embodiments”) for implementing a multilayer substrate according to the present disclosure will be described in detail below with reference to the accompanying drawings. Note that the wiring board according to the present disclosure is not limited to the embodiments. In addition, respective embodiments can be appropriately combined within a range so as not to contradict each other in terms of processing content. Note that in the following description, the same reference signs are used for identical or similar components, and detailed descriptions thereof are omitted.

### First Embodiment

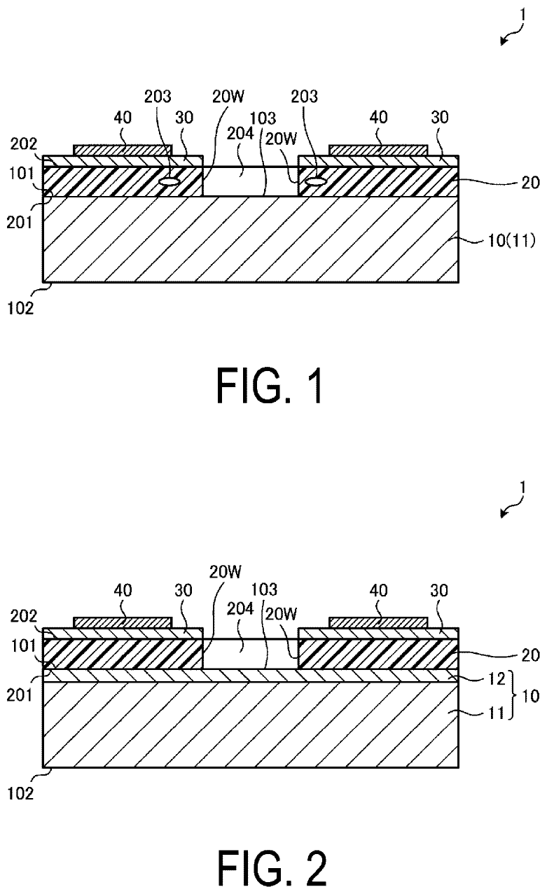

FIG. 1 is a cross-sectional view illustrating an example of a multilayer substrate according to a first embodiment. As illustrated in FIG. 1, a multilayer substrate 1 according to the first embodiment includes a substrate 10 and an organic resin layer 20.

The substrate 10 has surfaces 101 and 102 located at both ends in a thickness direction. The surface 101 is located on the organic resin layer 20 side. The surface 102 is located on an opposite side to the organic resin layer 20.

In other words, the substrate 10 has the surface 101 and the surface 102. The substrate 10 may have a so-called hexahedral shape. The surfaces 101 and 102 may be surfaces having the largest area in the hexahedron. The surface 101 and the surface 102 may be arranged on opposing sides of the substrate 10, as illustrated in FIG. 1. That is, the surface 101 and the surface 102 are arranged on opposing sides of the substrate 10, and may constitute main surfaces, respectively.

The substrate 10 includes a carbonaceous base member layer 11. The main material of the carbonaceous base member layer 11 may be, for example, graphite. The carbonaceous base member layer 11 may be, for example, a graphite sheet.

The substrate 10 may be constituted by the carbonaceous base member layer 11. The carbonaceous base member layer 11 may be used as the substrate 10. The substrate 10 may be the carbonaceous base member layer 11. In this case, the substrate 10 has a function as a so-called heat dissipation substrate having high heat dissipation.

The organic resin layer 20 is located on the substrate 10. The organic resin layer 20 is located on the carbonaceous base member layer 11. The organic resin layer 20 has surfaces 201 and 202 located at both ends in the thickness direction. The surface 201 is located on the substrate 10 side, and the surface 202 is located on an opposite side to the substrate 10.

The organic resin layer 20 is a so-called organic base member including a polymer material, for example. The organic resin layer 20 may be, for example, an epoxy resin, an acrylic resin, a polycarbonate resin, a polyimide resin, an olefin resin, or a polyphenylene resin. The organic resin layer 20 may be, for example, polytetrafluoroethylene (PTFE) or other fluororesin, or polyphenylene ether resin.

In the multilayer substrate 1, the carbonaceous base member layer 11 has a higher coefficient of thermal conductivity than that of the organic resin layer 20. Therefore, the multilayer substrate 1 having high heat dissipation is obtained.

In addition, in the multilayer substrate 1, the carbonaceous base member layer 11 may have a volume fraction larger than that of the organic resin layer 20. Here, the volume fraction of the carbonaceous base member layer 11 refers to a volume ratio of the carbonaceous base member layer 11 to the members constituting the multilayer substrate 1. Similarly, the volume fraction of the organic resin layer 20 refers to a volume ratio of the organic resin layer 20 to the members constituting the multilayer substrate 1. When the volume of the carbonaceous base member layer 11 is defined as V1, the volume of the organic resin layer 20 is defined as V2, and the total volume of V1 and V2 is defined as V0, the volume fraction (V1/(V1+V2)) of the carbonaceous base member layer 11 may have a value exceeding 0.5. By increasing the volume ratio of the carbonaceous base member layer 11 having a higher coefficient of thermal conductivity than that of the organic resin layer 20, the heat dissipation of the multilayer substrate 1 can be maintained at a high level.

In addition, the organic resin layer 20 may include carbon particles located in a polymer material. In other words, the organic resin layer 20 may be a composite material in which the polymer material and the carbon particles are combined. The organic resin layer 20 includes the same chemical component as that of the adjacent carbonaceous base member layer 11, and thus the C—C bonding strength is improved by the bonding, and the durability of the multilayer substrate 1 is improved. Note that the organic resin layer 20 may include inorganic particles such as silica and alumina, in addition to the carbon particles.

Additionally, the organic resin layer 20 may partially have a void portion 203. The presence of the void portion 203 further reduces the volume ratio of the organic resin layer 20 in the multilayer substrate 1. Thus, the heat dissipation of the multilayer substrate 1 can be further enhanced. Here, the shape or contour of the void portion 203 corresponds to an open pore and a closed pore.

In addition, the organic resin layer 20 may have a through hole 204, in addition to the void portion 203. Here, the through hole 204 refers to a space penetrating between the surface 201 and the surface 202 of the organic resin layer 20. Accordingly, heat transfer in a lateral direction intersecting the thickness direction of the organic resin layer 20 is less likely to occur, while heat transfer to the carbonaceous base member layer 11 side having a higher coefficient of thermal conductivity than that of the organic resin layer 20 is likely to occur. Therefore, the heat dissipation in the thickness direction (stacking direction) of the multilayer substrate 1 can be enhanced.

In comparison with the sizes of the void portions 203 and the through hole 204, when an average value obtained by measuring the individual maximum diameters of a plurality of void portions 203 is set to 1, the maximum diameter of the through hole 204 may be set to 10 or more and 10000 or less as a reference. Here, the maximum diameter of the through hole 204 may be defined as the larger one of the maximum value of the diameter of the space portion forming the through hole 204 and the maximum value of the length of the organic resin layer 20 in the thickness direction.

In addition, the number frequency or volume of the void portions 203 may have a higher distribution on one side in the thickness direction than on the other side when the organic resin layer 20 is equally divided into two in the thickness direction. For example, it is assumed that a heat-generating electric element such as a semiconductor element is arranged in the through hole 204. In such a case, a position of the electric element in the thickness direction of the organic resin layer 20 is preferably on a side where the number frequency or the volume of the void portions 203 is higher. Here, the volume refers to a total volume of individual volumes of the plurality of void portions 203 included in a volume of a specific portion of the organic resin layer 20.

Furthermore, the void portions 203 may be present so as to surround the periphery of the through hole 204 with a higher number frequency or volume than other portions. Here, the region where the void portions 203 are present so as to surround the through hole with a higher number frequency or volume is defined as follows.

The region where the number frequency of the void portions 203 is high is a region where the number frequency is 1.5 or more when the number frequency of the region where the number frequency of the void portions 203 is low is 1. The region where the volume of the void portion 203 is high is a region where the volume of the void portion 203 is 1.5 or more when the volume of the region where the volume of the void portion is low is 1.

In addition, the multilayer substrate 1 may include a metal wiring layer 30 located on the surface 202, which is a surface of the organic resin layer 20. Additionally, the multilayer substrate 1 may include an insulating solder resist layer 40 that partially covers a surface of the wiring layer 30.

In addition, the multilayer substrate 1 may include a mounting surface 103 on which an electric element is mounted. The mounting surface 103 is, for example, a portion of the surface 101 of the substrate 10 where the through hole 204 of the organic resin layer 20 is located. The electric element may be, for example, a light emitting element. The electric element may be a heat-generating source that generates heat by energization.

Note that although FIG. 1 illustrates a state in which the organic resin layer 20 is in contact with the carbonaceous base member layer 11, the organic resin layer 20 may be arranged to be partially or entirely separated from the carbonaceous base member layer 11 in the multilayer substrate 1. That is, the organic resin layer 20 may be located above the carbonaceous base member layer 11.

### Second Embodiment

FIG. 2 is a cross-sectional view illustrating an example of a multilayer substrate according to a second embodiment. In this case, also in the multilayer substrate 1 illustrated as the second embodiment, as illustrated in FIG. 2, the same reference signs as those of the multilayer substrate 1 of the first embodiment illustrated in FIG. 1 are used. This is used for convenience because the multilayer substrate of the second embodiment is based on the multilayer substrate 1 of the first embodiment. The multilayer substrate 1 described below is the multilayer substrate 1 according to the second embodiment.

As illustrated in FIG. 2, the multilayer substrate 1 may include an intermediate member layer 12. In this case, the intermediate member layer 12 is arranged between the carbonaceous base member layer 11 and the organic resin layer 20. The intermediate member layer 12 may be, for example, a metal plate.

In the multilayer substrate 1, the carbonaceous base member layer 11, the intermediate member layer 12, and the organic resin layer 20 may be arranged in the stacking direction such that the coefficient of thermal expansion increases in this order. Since the intermediate member layer 12 having a coefficient of thermal expansion between those of the carbonaceous base member layer 11 and the organic resin layer 20 is positioned between the carbonaceous base member layer 11 and the organic resin layer 20, stress generated between the carbonaceous base member layer 11 and the organic resin layer 20 can be relaxed. In addition, thermal deformation of the multilayer substrate 1 caused by a rapid temperature change can be reduced.

The coefficients of thermal expansion of the respective members constituting the multilayer substrate 1 may have a relationship of (carbonaceous base member layer 11)<(intermediate member layer 12)<(organic resin layer 20). As specific values of the coefficient of thermal expansion, for example, the coefficient of thermal expansion of the carbonaceous base member layer 11 may be 1×10⁻⁶/K or more and 5×10⁻⁶/K or less, the coefficient of thermal expansion of the intermediate member layer 12 may be 12×10⁻⁶/K or more and 17×10⁻⁶/K or less, and the coefficient of thermal expansion of the organic resin layer 20 may be 22×10⁻⁶/K or more and 30×10⁻⁶/K or less.

In addition, in the multilayer substrate 1, the carbonaceous base member layer 11, the intermediate member layer 12, and the organic resin layer 20 may be arranged in the stacking direction such that the coefficient of thermal conductivity decreases in this order. For example, in a case where a heat-generating electric element such as a light emitting element is mounted on the organic resin layer 20 side, when a member having a high coefficient of thermal conductivity is positioned away from the electric element, the carbonaceous base member layer 11 side having a large surface area is arranged to be largely exposed to the outside air. Therefore, heat is more likely to be dissipated from the carbonaceous base member layer 11 side having a higher coefficient of thermal conductivity than that of the organic resin layer 20. As a result, the multilayer substrate 1 can maintain high heat dissipation as a whole.

The coefficients of thermal conductivity of the respective members constituting the multilayer substrate 1 may have a relationship of (carbonaceous base member layer 11)>(intermediate member layer 12)>(organic resin layer 20). As specific values of the coefficient of thermal conductivity, for example, the coefficient of thermal conductivity of the carbonaceous base member layer 11 may be 1500 W/m·K or more and 2000 W/m·K or less, the coefficient of thermal conductivity of the intermediate member layer 12 may be 300 W/m·K or more and 500 W/m·K or less, and the coefficient of thermal conductivity of the organic resin layer 20 may be 0.005 W/m·K or more and 3 W/m·K or less.

### Third Embodiment

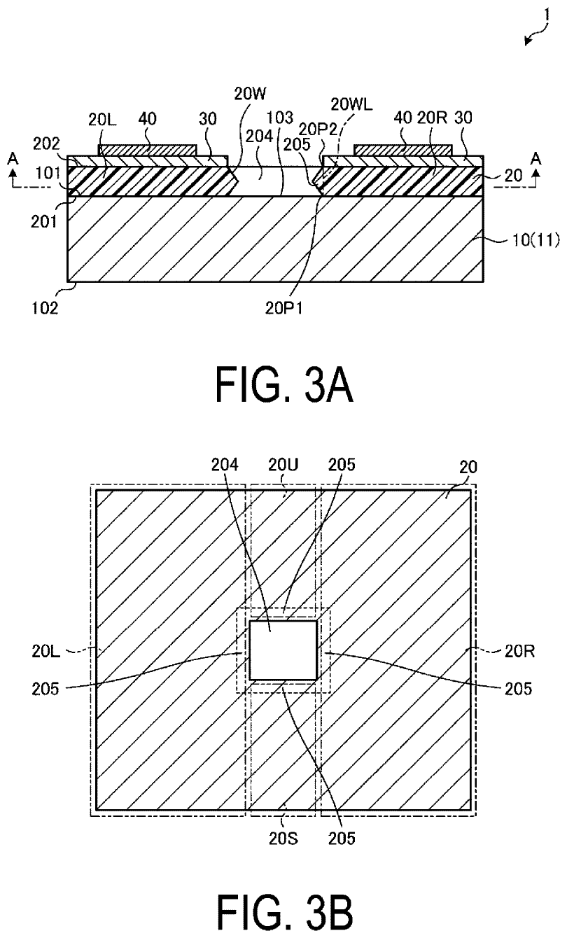

FIG. 3A is a cross-sectional view illustrating an example of a multilayer substrate according to a third embodiment. FIG. 3B is a cross-sectional view taken along line A-A illustrated in FIG. 3A. In this case, also in the multilayer substrate 1 illustrated as the third embodiment, the same reference signs as those of the multilayer substrate 1 of the first embodiment illustrated in FIG. 1 and the multilayer substrate 1 of the second embodiment illustrated in FIG. 2 are used. This is used for convenience because the multilayer substrate of the third embodiment is also based on the multilayer substrate 1 of the first embodiment. The multilayer substrate 1 described below is the multilayer substrate 1 according to the third embodiment.

The multilayer substrate 1 of the third embodiment illustrated in FIGS. 3A and 3B is different from the multilayer substrate 1 illustrated in FIG. 2 in terms of the shape of the through hole. As illustrated in FIGS. 3A and 3B, the through hole 204 formed in the multilayer substrate 1 of the third embodiment may have a drum shape. The shape of the through hole 204 mentioned here is a shape of the space portion provided in the organic resin layer 20.

The through hole 204 will be described again with reference to FIGS. 3A and 3B. As illustrated in FIGS. 3A and 3B, the organic resin layer 20 constituting the multilayer substrate 1 of the third embodiment is divided in a plane.

In this case, for convenience, the right portion of the organic resin layer 20 illustrated in FIG. 3B is referred to as an organic resin layer first portion 20R, and the left portion is referred to as an organic resin layer second portion 20L. In addition, the upper portion of the organic resin layer 20 illustrated in FIG. 3B is referred to as an organic resin layer third portion 20U, and the lower portion of the organic resin layer 20 is referred to as an organic resin layer fourth portion 20S.

The through hole 204 having a drum shape means that, referring to FIG. 3A, the organic resin layer first portion 20R and the organic resin layer second portion 20L each have a protruding portion 205 toward the through hole 204. Note that in the organic resin layer 20, the organic resin layer third portion 20U and the organic resin layer fourth portion 20S illustrated in FIG. 3B may each have the protruding portion 205.

In FIGS. 3A and 3B, when surfaces of the organic resin layer first portion 20R, the organic resin layer second portion 20L, the organic resin layer third portion 20U, and the organic resin layer fourth portion 20S constituting the organic resin layer 20, which are in contact with the through hole 204, are defined as inner walls 20W, the protruding portion 205 is a portion where the inner wall 20W protrudes in a convex shape toward the through hole 204. In other words, the protruding portion 205 is a portion including a surface (inner wall 20W) connecting the surface 201 and the surface 202 constituting the organic resin layer 20.

That is, when a connection point 20P1 between the surface 201 and the inner wall 20W and a connection point 20P2 between the surface 202 and the inner wall 20W are connected by a line 20WL, the protruding portion 205 is a portion protruding toward the through hole 204 from the line 20WL. Note that in the multilayer substrate 1, the protruding portion 205 is preferably formed so as to surround the through hole 204. In other words, the organic resin layer first portion 20R, the organic resin layer second portion 20L, the organic resin layer third portion 20U, and the organic resin layer fourth portion 20S constituting the organic resin layer 20 each have the inner wall 20W on the through hole 204 side, and the inner walls 20W are connected around the through hole 204. The protruding portions 205 including the inner walls 20W of the through hole 204 may be arranged so as to extend from the organic resin layer first portion 20R to the organic resin layer third portion 20U via the organic resin layer fourth portion 20S and the organic resin layer second portion 20L. In this case, the protruding portions 205 are preferably integrated within a range from the organic resin layer first portion 20R to the organic resin layer third portion 20U via the organic resin layer fourth portion 20S and the organic resin layer second portion 20L.

Here, an opening diameter of the through hole 204 is formed so as to be minimized at any position in the thickness direction between the surface 201 and the surface 202. The opening diameter of the through hole 204 may be formed so as to be minimized at the center in the thickness direction of the organic resin layer 20. The opening diameter of the through hole 204 may be the same or different between a diameter at a position on the surface 201 and a diameter at a position on the surface 202. When the diameter at the position on the surface 201 and the diameter at the position on the surface 202 are different diameters, a position of an apex portion of the protruding portion 205 in the thickness direction may be shifted toward either the surface 201 side or the surface 202 side. In this case, the position of the apex portion of the protruding portion 205 in the thickness direction is preferably closer to the smaller diameter side. Here, the diameter is a diameter (maximum diameter) at which a value of the diameter becomes maximum when the diameter of the through hole 204 is measured.

For example, when a thermally conductive member such as a thermal interface material (TIM) is inserted into the through hole 204, the inserted thermally conductive member tends to conform to the shape of the inner walls 20W of the through hole 204. The presence of the protruding portion 205 makes it difficult for the thermally conductive member in the through hole 204 to come off to the outside. Therefore, it is possible to ensure stable heat dissipation. For example, the multilayer substrate 1 can be suitably used in a device that undergoes large vibrations.

Note that the protruding portion 205 may be located over the entire periphery of the through hole 204 or may be located in a part of the periphery of the through hole 204.

### Fourth Embodiment

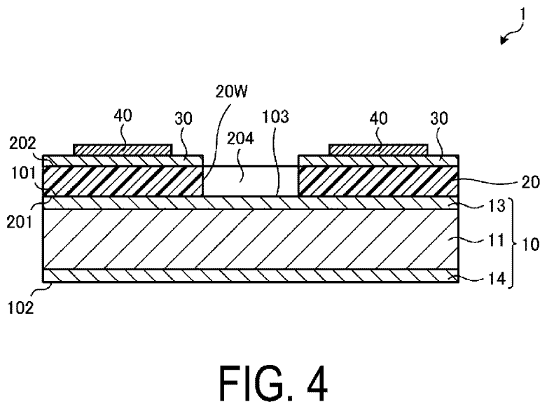

FIG. 4 is a cross-sectional view illustrating an example of a multilayer substrate according to a fourth embodiment. In this case, also in the multilayer substrate 1 illustrated as the fourth embodiment, the same reference signs as those of the multilayer substrate 1 of the first embodiment illustrated in FIG. 1 and the multilayer substrate 1 of the second embodiment illustrated in FIG. 2 are used. This is used for convenience because the multilayer substrate of the fourth embodiment is also based on the multilayer substrate 1 of the first embodiment. The multilayer substrate 1 described below is the multilayer substrate 1 according to the fourth embodiment. As illustrated in FIG. 4, in the multilayer substrate 1 of the fourth embodiment, the substrate 10 may include a second intermediate member layer 14, in addition to the first intermediate member layer 13.

The second intermediate member layer 14 may be located on an opposite side to the first intermediate member layer 13 with the carbonaceous base member layer 11 interposed therebetween. The first intermediate member layer 13 may be located between the carbonaceous base member layer 11 and the organic resin layer 20, and may be located on the surface 101 side of the substrate 10. The second intermediate member layer 14 may be located on an opposite side to the organic resin layer 20 with the first intermediate member layer 13 and the carbonaceous base member layer 11 interposed therebetween. That is, the second intermediate member layer 14 may be located on the surface 102 side of the substrate 10. The first intermediate member layer 13 and the second intermediate member layer 14 may be, for example, metal plates. In this manner, by positioning the first intermediate member layer 13 and the second intermediate member layer 14 so as to sandwich the carbonaceous base member layer 11 therebetween, the rigidity of the carbonaceous base member layer 11 can be increased, and the multilayer substrate 1 is less likely to be deformed. In this case, the elastic moduli (Young's moduli) of the first intermediate member layer 13 and the second intermediate member layer 14 are preferably higher than the elastic modulus (Young's modulus) of the carbonaceous base member layer 11.

In addition, the first intermediate member layer 13 and the second intermediate member layer 14 may have the same average thickness or different average thicknesses. In addition, of the first intermediate member layer 13 and the second intermediate member layer 14, the thickness of the first intermediate member layer 13 on which an electric element is mounted may be made greater than the thickness of the second intermediate member layer 14. The reason is that the first intermediate member layer 13 on which the electric element is mounted is more susceptible to thermal load and deformation than the second intermediate member layer 14.

### Manufacturing Method

An example of a manufacturing method of the multilayer substrate 1 of the present disclosure will be specifically described below. Note that the present disclosure is not limited to the multilayer substrate 1 manufactured by the following manufacturing method.

First, a graphite sheet is prepared. In addition, an uncured sheet including silica powder in a thermosetting epoxy resin is prepared. The addition amount of silica powder may be, for example, 150 parts by mass relative to 100 parts by mass of the epoxy resin.

Next, a through hole (for example, 500 μm square) is formed in the fabricated uncured sheet, and a wiring sheet is fabricated using the uncured sheet. The wiring sheet is formed by, for example, forming a wiring pattern made of copper foil on one surface of the uncured sheet by a transfer method. In addition, the wiring pattern is arranged in a region excluding the through hole, for example. The wiring pattern made of copper foil used in the transfer method is obtained by, for example, attaching a solid copper foil to a PET film and patterning the copper foil by etching.

The fabricated wiring sheet is stacked on the graphite sheet, which is then heated under pressure to obtain a base body of a multilayer substrate. The pressurization and heating conditions may be set to, for example, a temperature of 200° C., a pressure of 0.1 MPa, and a heating time of 5 hours. The obtained base body is cut into a predetermined size, thereby obtaining a multilayer substrate. When a composite sheet in which a copper foil is stacked on graphite is used instead of the graphite sheet, the same conditions as described above can be used.

Note that, for example, when manufacturing the multilayer substrate 1 including the organic resin layer 20 having the protruding portions 205 illustrated in FIGS. 3A and 3B, the through hole 204 may be formed by setting the pressure condition at the time of the above-described pressurization and heating to be high (for example, 0.13 MPa).

While the present disclosure has been described in detail, the present disclosure is not limited to the aforementioned embodiments, and various changes, improvements, and the like can be made without departing from the gist of the present disclosure.

In one embodiment, (1) a multilayer substrate includes a carbonaceous base member layer and an organic resin layer, wherein

the organic resin layer is located on the carbonaceous base member layer, and

the carbonaceous base member layer has a higher coefficient of thermal conductivity than that of the organic resin layer.

(2) In the multilayer substrate according to (1), the carbonaceous base member layer may have a larger volume fraction than the organic resin layer.

(3) The multilayer substrate according to (1) or (2) may further include a first intermediate member layer, wherein

the first intermediate member layer is located between the carbonaceous base member layer and the organic resin layer, and

the carbonaceous base member layer, the first intermediate member layer, and the organic resin layer may have coefficients of thermal expansion that increase in this order.

(4) In the multilayer substrate according to (3), the carbonaceous base member layer, the first intermediate member layer, and the organic resin layer may have coefficients of thermal conductivity that decrease in this order.

(5) In the multilayer substrate according to any one of (1) to (4), the organic resin layer may include a void portion.

(6) The multilayer substrate according to (5) may further include a through hole.

(7) In the multilayer substrate according to (6), the through hole may have a drum shape.

(8) The multilayer substrate according to (3) or (4) may further include a second intermediate member layer, wherein

the second intermediate member layer may be located on a surface of the carbonaceous base member layer opposite to a surface on which the first intermediate member layer is located.

(9) In the multilayer substrate according to any one of (1) to (8), a main material of the carbonaceous base member layer may be graphite.

(10) In the multilayer substrate according to any one of (1) to (9), the organic resin layer may include a polymer material and a carbon particle.

Additional effects and other aspects can be easily derived by one skilled in the art. Thus, the broader aspects of the present disclosure are not limited to the specific details and representative embodiments illustrated and described above. Accordingly, various changes can be made without departing from the spirit or scope of the general inventive concepts defined by the appended claims and their equivalents.

1. A multilayer substrate comprising:
a carbonaceous base member layer; and
an organic resin layer, wherein
the organic resin layer is located on the carbonaceous base member layer, and
the carbonaceous base member layer has a higher coefficient of thermal conductivity than that of the organic resin layer.

2. The multilayer substrate according to claim 1, wherein the carbonaceous base member layer has a larger volume fraction than the organic resin layer.

3. The multilayer substrate according to claim 1, further comprising a first intermediate member layer, wherein
the first intermediate member layer is located between the carbonaceous base member layer and the organic resin layer, and
the carbonaceous base member layer, the first intermediate member layer, and the organic resin layer have coefficients of thermal expansion that increase in this order.

4. The multilayer substrate according to claim 3, wherein the carbonaceous base member layer, the first intermediate member layer, and the organic resin layer have coefficients of thermal conductivity that decrease in this order.

5. The multilayer substrate according to claim 1, wherein the organic resin layer comprises a void portion.

6. The multilayer substrate according to claim 5, wherein the organic resin layer further comprises a through hole.

7. The multilayer substrate according to claim 6, wherein the through hole has a drum shape.

8. The multilayer substrate according to claim 3, further comprising a second intermediate member layer, wherein
the second intermediate member layer is located on a surface of the carbonaceous base member layer opposite to a surface on which the first intermediate member layer is located.

9. The multilayer substrate according to claim 1, wherein a main material of the carbonaceous base member layer is graphite.

10. The multilayer substrate according to claim 1, wherein the organic resin layer comprises a polymer material and a carbon particle.
